(19) United States
(12) Patent Application Publication
(10) Pub. No.: US 2014/0327062 A1
(43) Pub. Date: Nov. 6, 2014

(54) ELECTRONIC DEVICES INCLUDING OXIDE DIELECTRIC AND INTERFACE LAYERS

(71) Applicants: Ki-Yeon PARK, Hwaseong-si (KR); Hyun-Jun Kim, Seoul (KR); Se-Hyoung Ahn, Seoul (KR); Young-Geun Park, Suwon-si (KR); Ki-Vin Im, Seongnam-si (KR)

(72) Inventors: Ki-Yeon PARK, Hwaseong-si (KR); Hyun-Jun Kim, Seoul (KR); Se-Hyoung Ahn, Seoul (KR); Young-Geun Park, Suwon-si (KR); Ki-Vin Im, Seongnam-si (KR)

(21) Appl. No.: 14/073,354

(22) Filed: Nov. 6, 2013

(30) Foreign Application Priority Data
May 3, 2013 (KR) 10-2013-0050114

(51) Int. Cl. H01L 49/02; H01L 27/108

(52) U.S. Cl. CPC H01L 28/60; H01L 27/108
USPC 257/296; 257/773; 257/768; 257/770; 257/771; 257/532

(57) ABSTRACT

An electronic device may include a substrate, an oxide dielectric layer on the substrate, an interface layer on the oxide dielectric layer, and an electrode on the interface layer. The oxide dielectric layer may include an aluminum oxide layer between first and second zirconium oxide layers. The interface layer may have a first formation enthalpy, and the oxide dielectric layer may be between the substrate and the interface layer. The electrode may have a second formation enthalpy higher than the first formation enthalpy, and the interface layer may be between the oxide dielectric layer and the electrode.

### CROSS-REFERENCE TO RELATED APPLICATION

This application claims priority from Korean Patent Application No. 10-2013-0050114, filed on May 3, 2013, in the Korean Intellectual Property Office, and all the benefits accruing therefrom under 35 U.S.C. 119, the disclosure of which is hereby incorporated herein in its entirety by reference.

### BACKGROUND

1. Field of Inventive Concepts

Present inventive concepts relate to semiconductor devices and methods for fabricating the same.

2. Description of Related Art

In accordance with the recent trends toward large-capacity and highly integrated semiconductor devices, design rules of semiconductor devices are continuously decreasing. Such trends also apply to dynamic random access memories (DRAMs), which are semiconductor memory devices. In order for a DRAM to operate, capacitance exceeding a predetermined level may be required for each cell. An increase in the capacitance may increase an amount of charge stored in a capacitor, thereby improving a refresh characteristic of a semiconductor device. Improved refresh characteristics of semiconductor memory devices may increase yields.

### SUMMARY

Present inventive concepts may provide semiconductor devices having improved capacitance and/or reliability by preventing/reducing loss of oxygen atoms in a dielectric layer using an interfacing technique between the dielectric layer and an electrode.

Present inventive concepts may also provide methods for fabricating such semiconductor devices.

These and other objects of present inventive concepts will be described in and/or be apparent from the following description of some example embodiments.

According to some embodiments of present inventive concepts, a semiconductor device may include a first conductor, an oxide dielectric layer on the first conductor, an interface layer on the oxide dielectric layer having a first formation enthalpy and donating oxygen, and a second conductor on the interface layer in contact with the interface layer and having a second formation enthalpy higher than the first formation enthalpy.

According to other embodiments of present inventive concepts, a semiconductor device may include a first conductor, an oxide dielectric layer on the first conductor, an insertion layer on the oxide dielectric layer and preventing/reducing oxygen atoms from being diffused from the oxide dielectric layer, a second conductor on the insertion layer and having first formation enthalpy, and an interface layer between the insertion layer and the second conductor to be in contact with the insertion layer and the second conductor, having second formation enthalpy lower than the first formation enthalpy and donating oxygen atoms to the second conductor.

According to still other embodiments of present inventive concepts, a semiconductor device may include a transistor having first and second impurity regions, a bit line electrically connected to the first impurity region through a first contact plug, a lower electrode protruding on the transistor and extending in one direction and electrically connected to the second impurity region through a second contact plug, an oxide dielectric layer on the lower electrode, an interface layer on the oxide dielectric layer, made of a metal oxide, and having first formation enthalpy, and an upper electrode on the interface layer in contact with the interface layer, made of a metal nitride, and having second formation enthalpy higher than the first formation enthalpy.

According to yet other embodiments of present inventive concepts, a semiconductor device may include a lower conductor, a metal oxide dielectric layer on the lower conductor, a titanium oxide layer on the metal oxide dielectric layer and preventing/reducing oxygen from being diffused from the metal oxide dielectric layer, and an upper conductor on the titanium oxide layer in contact with the titanium oxide layer.

According to some embodiments, an electronic device may include a substrate, an oxide dielectric layer on the substrate, an interface layer on the oxide dielectric layer, and an electrode on the interface layer. The oxide dielectric layer may include an aluminum oxide layer between first and second zirconium oxide layers. The interface layer may have a first formation enthalpy, and the oxide dielectric layer may be between the substrate and the interface layer. The electrode may have a second formation enthalpy higher than the first formation enthalpy, and the interface layer may be between the oxide dielectric layer and the electrode.

The interface layer may include an oxide of at least one of titanium (Ti), aluminum (Al), and/or manganese (Mn).

The interface layer may include at least one of TiₓO_{y}, AlₓO_{y}, TiₓAl_{z}O_{y}, and/or MnₓO_{y} where a ratio of a number of oxygen atoms to a number of metal atoms is in the range of 1 to 2. The ratio of the number of oxygen atoms to the number of metal atoms may be greater than 1 and no greater than 2. The ratio of the number of oxygen atoms to the number of metal atoms may be greater than 1 and less than 2.

The interface layer may include a conductive oxide of at least one of titanium (Ti), aluminum (Al), manganese (Mn), and/or titanium (Ti) and aluminum (Al). The interface layer may include at least one of TiO₂, Ti₄O₇, Ti₃O₅, and/or Ti₂O₃.

The electrode may include a conductive metal nitride. The electrode may include a conductive nitride of at least one of titanium, zirconium, aluminum, hafnium, tantalum, niobium, yttrium, lanthanum, vanadium, and/or manganese.

The interface layer may include an oxide of a metal, and the electrode may include a nitride of the metal.

The interface layer may have a thickness in the range of about 1 Angstrom to about 10 Angstroms.

An insertion layer including an aluminum oxide layer may be provided between the oxide dielectric layer and the interface layer, and a material of the interface layer may be different than that of the insertion layer. The insertion layer may have a thickness in the range of about 1 Angstrom to about 5 Angstroms. A thickness of the interface layer may be greater than a thickness of the insertion layer.

The electrode may be a first electrode, and a second electrode may be provided between the substrate and the oxide dielectric layer.

The substrate may include a semiconductor active region having a channel region between first and second source/drain regions, and the oxide dielectric layer may be on the channel region between the channel region and the electrode.

A transistor may be provided on the substrate, and the transistor may include a channel region, first and second source/drain regions on opposite sides of the channel region, and a word line on the channel region. A bit line may be electrically coupled to the first source/drain region, a first capacitor electrode may be electrically coupled to the second source/drain region, the oxide dielectric layer may be on the first capacitor electrode so that the first capacitor electrode is between the oxide dielectric layer and the substrate, the oxide dielectric layer may be between the first capacitor electrode and the interface layer. and the electrode may be a second capacitor electrode.

The first capacitor electrode may be one of a cylindrical capacitor electrode and a columnar capacitor electrode.

The interface layer may include titanium oxide. Moreover, the titanium oxide may include TiₓO_{y}, where a ratio of y to x is in the range of 1 to 2, and/or the titanium oxide may have a non-stoichiometric composition.

According to some other embodiments, an electronic device may include a substrate, an oxide dielectric layer on the substrate, an interface layer on the oxide dielectric layer, and an electrode on the interface layer. The oxide dielectric layer may include an aluminum oxide layer between first and second zirconium oxide layers. The interface layer may include an oxide of at least one of titanium (Ti), aluminum (Al), and/or manganese (Mn). The oxide dielectric layer may be between the substrate and the interface layer The interface layer may be between the oxide dielectric layer and the electrode.

The interface layer may include at least one of TiₓO_{y}, AlₓO_{y}, TiₓAl_{z}O_{y}, and/or MnₓO_{y} where a ratio of a number of oxygen atoms to a number of metal atoms is in the range of 1 to 2. The ratio of the number of oxygen atoms to the number of metal atoms may be greater than 1 and no greater than 2. The ratio of the number of oxygen atoms to the number of metal atoms may be greater than 1 and less than 2.

The interface layer may include a conductive oxide of at least one of titanium (Ti), aluminum (Al), manganese (Mn), and/or titanium (Ti) and aluminum (Al). The interface layer may include at least one of TiO₂, Ti₄O₇, Ti₃O₅, and/or Ti₂O₃.

The electrode may include a conductive metal nitride. The electrode may include a conductive nitride of at least one of titanium, zirconium, aluminum, hafnium, tantalum, niobium, yttrium, lanthanum, vanadium, and/or manganese.

The interface layer may include an oxide of a selected one of titanium, aluminum, manganese, or titanium, and the electrode may include a nitride of the selected one of titanium aluminum, manganese, or titanium.

The interface layer may have a thickness in the range of about 1 Angstrom to about 10 Angstroms.

An insertion layer may include an aluminum oxide layer between the oxide dielectric layer and the interface layer, and a material of the interface layer may be different than that of the insertion layer. The insertion layer may have a thickness in the range of about 1 Angstrom to about 5 Angstroms. A thickness of the interface layer may be greater than a thickness of the insertion layer.

The electrode may be a first electrode, and a second electrode may be provided between the substrate and the oxide dielectric layer.

The substrate may include include a semiconductor active region having a channel region between first and second source/drain regions, and the oxide dielectric layer may be on the channel region between the channel region and the electrode.

A transistor may be provided on the substrate, and the transistor may include a channel region, first and second source/drain regions on opposite sides of the channel region, and a word line on the channel region. A bit line may be electrically coupled to the first source/drain region. A first capacitor electrode may be electrically coupled to the second source/drain region, the oxide dielectric layer may be on the first capacitor electrode so that the first capacitor electrode is between the oxide dielectric layer and the substrate, and the oxide dielectric layer may be between the first capacitor electrode and the interface layer. Moreover, the electrode may be a second capacitor electrode.

The first capacitor electrode may be one of a cylindrical capacitor electrode and a columnar capacitor electrode.

The interface layer may include titanium oxide. The titanium oxide may include TiₓO_{y}, where a ratio of y to x is in the range of 1 to 2. The titanium oxide may have a non-stoichiometric composition.

According to still other embodiments, an electronic device may include a first electrode, an oxide dielectric layer on the first electrode, an interface layer on the oxide dielectric layer, and a second electrode on the interface layer. The oxide dielectric layer may include an aluminum oxide layer between first and second zirconium oxide layers. The interface layer may include an oxide of at least one of titanium (Ti), aluminum (Al), and/or manganese (Mn), and the oxide dielectric layer may be between the first electrode and the interface layer. The interface layer may be between the oxide dielectric layer and the second electrode.

A substrate may be provided with the first electrode being between the substrate and the oxide dielectric layer.

The oxide dielectric layer may be thicker than the interface layer.

The interface layer may include a titanium oxide layer directly on one of the first and second zirconium oxide layers of the oxide dielectric layer.

The interface layer may include an oxide of at least one of titanium (Ti), aluminum (Al), and/or manganese (Mn).

The interface layer may include at least one of TiₓO_{y}, AlₓO_{y}, TiₓAl_{z}O_{y}, and/or MnₓO_{y} where a ratio of a number of oxygen atoms to a number of metal atoms is in the range of 1 to 2. The ratio of the number of oxygen atoms to the number of metal atoms may be greater than 1 and no greater than 2. The ratio of the number of oxygen atoms to the number of metal atoms may be greater than 1 and less than 2.

The interface layer may include a conductive oxide of at least one of titanium (Ti), aluminum (Al), manganese (Mn), and/or titanium (Ti) and aluminum (Al). The interface layer may include at least one of Ti₄O₇, Ti₃O₅, and/or Ti₂O₃.

The second electrode may include a conductive metal nitride. The second electrode may include a conductive nitride of at least one of titanium, zirconium, aluminum, hafnium, tantalum, niobium, yttrium, lanthanum, vanadium, and/or manganese.

The interface layer may include an oxide of a metal and the second electrode may include a nitride of the metal.

The interface layer may have a thickness in the range of about 1 Angstrom to about 10 Angstroms.

An insertion layer may include an aluminum oxide layer between the oxide dielectric layer and the interface layer, and a material of the interface layer may be different than that of the insertion layer.

The interface layer may be directly on the insertion layer. The insertion layer may have a thickness in the range of about 1 Angstrom to about 5 Angstroms. A thickness of the interface layer may be greater than a thickness of the insertion layer. The oxide dielectric layer may be thicker than the interface layer, and the interface layer may be thicker than the insertion layer.

A substrate may be provided with the first electrode being between the substrate and the oxide dielectric layer. A transistor may be provided on the substrate, with the transistor including a channel region, first and second source/drain regions on opposite sides of the channel region, and a word line on the channel region. A bit line may be electrically coupled to the first source/drain region, and the first electrode may be electrically coupled to the second source/drain region.

The first electrode may include one of a cylindrical capacitor electrode and a columnar capacitor electrode. The interface layer may include titanium oxide. The titanium oxide may include TiₓO_{y}, where a ratio of y to x is in the range of 1 to 2. The titanium oxide may have a non-stoichiometric composition.

### BRIEF DESCRIPTION OF THE DRAWINGS

The above and other features and advantages of present inventive concepts will become more apparent by describing in detail examples of embodiments thereof with reference to the attached drawings in which:

FIG. 1 illustrates a semiconductor device according to first embodiments of present inventive concepts;

FIG. 2A is a diagram illustrating the formation enthalpy between a second conductor and an interface layer shown in FIG. 1, FIG. 2B is a graph illustrating the formation enthalpy between TiN and TiOₓ used as the second conductor and the interface layer shown in FIG. 1, respectively;

FIG. 3 illustrates a semiconductor device according to second embodiments of present inventive concepts;

FIG. 4 is a layout view illustrating semiconductor devices according to third and fourth embodiments of present inventive concepts;

FIG. 5 illustrates the semiconductor device according to third embodiments of present inventive concepts;

FIG. 6 illustrates the semiconductor device according to fourth embodiments of present inventive concepts;

FIG. 7 illustrates a semiconductor device according to fifth embodiments of present inventive concepts;

FIGS. 8 and 9 illustrate intermediate process steps in a method for fabricating semiconductor devices according to first embodiments of present inventive concepts;

FIG. 10 is a diagram illustrating a change in the formation enthalpy generated in an interface layer in the course of forming a second conductor;

FIG. 11 illustrates intermediate process steps in a method for fabricating the semiconductor device according to the second embodiments of present inventive concepts;

FIG. 12 is a block diagram illustrating an example of an electronic system including semiconductor devices according to embodiments of present inventive concepts; and

FIG. 13 is a block diagram illustrating an example of a memory card including semiconductor devices according to embodiments of present inventive concepts.

### DETAILED DESCRIPTION OF THE EMBODIMENTS

Present inventive concepts will now be described more fully hereinafter with reference to the accompanying drawings, in which examples of embodiments of inventive concepts are shown, Inventive concepts may, however, be embodied in different forms and should not be construed as limited to the embodiments set forth herein. Rather, these embodiments are provided so that this disclosure will be thorough and complete, and will fully convey the scope of inventive concepts to those skilled in the art. The same reference numbers indicate the same components throughout the specification. In the attached figures, thicknesses of layers and/or regions may be exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will also be understood that when a layer/element is referred to as being “on” another layer/element or substrate, it can be directly on the other layer/element or substrate, or intervening layers/elements may also be present. In contrast, when a layer/element is referred to as being “directly on” another layer/element, there are no intervening layers/elements present.

It will be understood that, although the terms first, second, etc. may be used herein to describe various layers/elements, these layers/elements should not be limited by these terms. These terms are only used to distinguish one layer/element from another layer/element. Thus, for example, a first layer/element, a first component or a first section discussed below could be termed a second layer/element, a second component or a second section without departing from the teachings of present inventive concepts.

The use of the terms “a” and “an” and “the” and similar terms in the context of describing inventive concepts (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the inventive concepts belong. It is noted that the use of any and all examples, or exemplary terms provided herein is intended merely to better illuminate inventive concepts and is not a limitation on the scope of inventive concepts unless otherwise specified. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

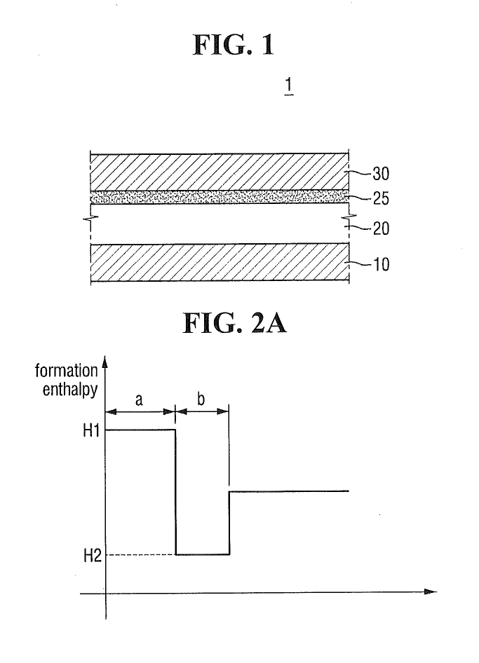

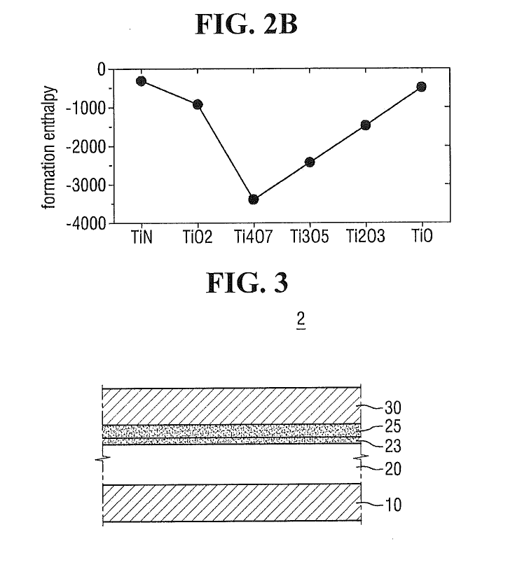

Hereinafter, a semiconductor device according to first embodiments of present inventive concepts will be described with reference to FIGS. 1 to 2B.

FIG. 1 illustrates a cross-sectional view of a semiconductor device according to first embodiments, and FIG. 2A is a diagram illustrating the formation enthalpy between a second conductor and an interface layer shown in FIG. 1. FIG. 2B is a graph illustrating the formation enthalpy between TiN and TiOₓ used as the second conductor and the interface layer shown in FIG. 1, respectively.

Referring to FIG. 1, semiconductor device 1 includes a first conductor 10, an oxide dielectric layer 20, an interface layer 25 and a second conductor 30.

The first conductor 10 may include at least one selected from the group consisting of doped polysilicon, a conductive metal nitrite (for example, titanium nitride, tantalum nitride or tungsten nitride), a metal (for example, ruthenium, iridium, titanium or tantalum), and a conductive metal oxide (for example, iridium oxide). Alternatively, the first conductor 10 may be a doped portion of a semiconductor substrate, for example, a P-type substrate, or an N-type substrate.

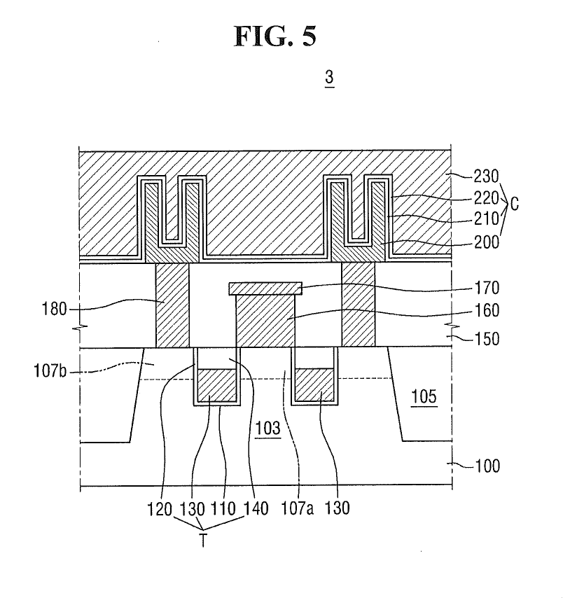

As will be described below with reference to FIGS. 5 to 7, the first conductor 10 may be a lower electrode of a capacitor. Alternatively, the first conductor 10 may be a channel region of a transistor.

The oxide dielectric layer 20 is formed on the first conductor 10. The oxide dielectric layer 20 may be, for example, a metal oxide dielectric layer, and may include a high-k dielectric layer. The high-k dielectric layer may include, for example, zirconium oxide (ZrO₂), hafnium oxide (HfO₂), zirconium silicon oxide (ZrSiOₓ), hafnium silicon oxide (HfSiOₓ), zirconium hafnium silicon oxide (ZrHfSiOₓ), aluminum oxide (Al₂O₃) and combinations thereof, but not limited thereto.

The interface layer 25 is formed on the oxide dielectric layer 20. The interface layer 25 may include, for example, an oxygen-containing compound, such as a metal oxide.

The interface layer 25 may include, for example, one of titanium oxide (TiOₓ, where 0<x<2), aluminum oxide (AlOₓ, where 1<x<2), titanium aluminum oxide (Ti_{y}Al_{1-y}Oₓ, where 0<x<2) and manganese oxide (MnOₓ, where 0<x<2). If the interface layer 25 is titanium aluminum oxide, a ratio of a metal element contained in the interface layer 25 to an aluminum element may be in a range of, for example, 0.001 to 0.5. In other words, the interface layer 25 may include a compound further including aluminum in titanium oxide.

The interface layer 25 may include at least one of TiₓO_{y}, AlₓO_{y}, TiₓAl_{z}, and/or MnₓO_{y} where a ratio of a number of oxygen atoms to a number metal atoms is in the range of 1 to 2. The ratio of the number of oxygen atoms to the number of metal atoms may be greater than 1 and no greater than 2, and more particularly, greater than 1 and less than 2.

In the metal oxide forming the interface layer 25, the metal contained in the metal oxide may be a transition metal and may have several oxidation numbers. Therefore, the metal contained in the metal oxide forming the interface layer 25 is bonded with oxygen, thereby forming compounds having various chemical formulas. For example, when the interface layer 25 is titanium oxide, titanium as a metal element contained in the titanium oxide may have multiple oxidation numbers, thereby forming a variety of oxides, including TiO, Ti₂O₃, Ti₃O₅, Ti₄O₇, and TiO₂,

The interface layer 25 may be sufficiently thin so that it does not act as a dielectric layer. The thickness of the interface layer 25 may be in a range of, for example, 1 Å (Angstrom) to 10 Å (Angstroms), In addition, the thickness of the interface layer 25 may be less than that of the oxide dielectric layer 20.

In the semiconductor device according to first embodiments, the interface layer 25 may be a conductive layer that is electrified. That is to say, the interface layer 25 formed on the oxide dielectric layer 20 may serve as an electrode or a portion of an electrode providing an electric signal/field to the oxide dielectric layer 20. During the manufacturing process of the semiconductor device, the interface layer 25 may be formed from a pre-interface layer (25a of FIG. 9), and it may include oxygen vacancies. Since oxygen vacancies in the interface layer 25 may form a current path, along which electrical current can flow, the interface layer 25 may be a conductive layer that is electrified.

The interface layer 25 can reduce/prevent diffusion of oxygen atoms contained in the oxide dielectric layer 20 into the second conductor 30, and may function as an oxygen donating layer providing oxygen atoms to the second conductor 30 during the manufacturing process of the semiconductor device. In addition, the interface layer 25 may reduce/prevent penetration of nitrogen atoms contained in the second conductor 30 into the oxide dielectric layer 20. Functions of the interface layer 25 will be described below in greater detail.

The second conductor 30 is formed on the interface layer 25 to be in contact with the interface layer 25. In detail, the second conductor 30 may make direct contact with the interface layer 25. The second conductor 30 may be made of a conductive metal nitride and may include, for example, at least one of titanium nitride (TiN), zirconium nitride (ZrN), aluminum nitride (AIN), hafnium nitride (HfN), tantalum nitride (TaN), niobium nitride (NbN), yttrium nitride (YN), lanthanium nitride (LaN), vanadium nitride (VN), and/or manganese nitride (Mn₄N).

As will be described below with reference to FIGS. 5 to 7, the second conductor 30 may be an upper electrode of a capacitor. Alternatively, the second conductor 30 may be a gate electrode of a transistor.

First, reducing/preventing diffusion of oxygen atoms contained in the oxide dielectric layer 20 into the second conductor 30, which may be a function of the interface layer 25, will be described in view of formation enthalpy.

The relationship between the interface layer 25 and the second conductor 30 may be as follows. Formation enthalpy having a negative value may suggest that the energy state of a reaction start material is higher than that of a reaction end product, and formation enthalpy having a positive value may suggest that the energy state of a reaction start material is lower than that of a reaction end product. From the view point of stoichiometry, a substance generally tends to move to a lower energy state. This tendency may change according to ambient reaction conditions, though.

Referring to FIGS. 1 and 2A, reference symbol a denotes the second conductor 30, and reference symbol b denotes the interface layer 25. In addition, a portion existing at the right side of b (i.e., below the interface layer 25), denotes the oxide dielectric layer 20. The second conductor 30 may have first formation enthalpy H1, and the interface layer 25 may have second formation enthalpy H2. The first formation enthalpy H1 is higher than the second formation enthalpy H2. That is to say, the formation enthalpy H1 of the second conductor 30 is higher than the formation enthalpy H2 of the interface layer 25.

FIG. 2A shows that the formation enthalpy of the oxide dielectric layer 20 may be positioned between the formation enthalpy H1 of the second conductor 30 and the formation enthalpy H2 of the interface layer 25, which is, however, provided only for illustration, but aspects of present inventive concepts are not limited thereto.

In semiconductor devices according to embodiments of present inventive concepts, the formation enthalpy H2 of the metal oxide forming the interface layer 25 may be the lowest one of formation enthalpies of compounds that can be formed by binding metal elements of the metal oxide forming the interface layer 25 with oxygen atoms.

A substance having low formation enthalpy may be in a more stable state than a substance having high formation enthalpy. That is to say, in order to convert the substance having low formation enthalpy into the substance having high formation enthalpy, a relatively large amount of energy may be required. In order to allow oxygen atoms to diffuse from the oxide dielectric layer 20 and then move to the second conductor 30, the oxygen atoms should pass through the interface layer 25. However, since the formation enthalpy H2 of the interface layer 25 is lowest among formation enthalpies of compounds that can be formed by binding metal elements of the metal oxide forming the interface layer 25 with the oxygen atoms, the oxygen atoms contained in the oxide dielectric layer 20 are diffused into the interface layer 25, so that an oxygen concentration of the interface layer 25 may increase. In such a case, the formation enthalpy of the interface layer 25 may increase.

However, a substance may tend to be maintained at a lower energy state. Thus, even if the oxygen atoms diffuse from the oxide dielectric layer 20, they may not pass through an interface between the interface layer 25 and the oxide dielectric layer 20. That is to say, the interface layer 25 may reduce/prevent diffusion of oxygen atoms contained in the oxide dielectric layer 20 into the second conductor 30. In other words, the interface layer 25 having low formation enthalpy is positioned between the second conductor 30 and the oxide dielectric layer 20. That is to say, the interface layer 25 may function as a potential barrier, thereby reducing/preventing movement of the oxygen atoms contained in the oxide dielectric layer 20 to the second conductor 30,

From the view point of formation enthalpy, the interface layer 25 may include, for example, one of titanium oxide (TiOₓ, where 0<x<2), aluminum oxide (AlOₓ, where 1<x<2), titanium aluminum oxide (Ti_{y}Al_{1-y}Oₓ, where 0<x<2) and manganese oxide (MnOₓ where 0<x<2). In addition, the second conductor 30 may include, for example, one of titanium nitride (TiN), zirconium nitride (ZrN), aluminum nitride (AIN), hafnium nitride (HfN), tantalum nitride (TaN), niobium nitride (NbN), yttrium nitride (YN), lanthanium nitride (LaN), vanadium nitride (VN), and/or manganese nitride (Mn₄N).

In more detail, in a case where TiN and TiOₓ are used as the second conductor 30 and the interface layer 25, respectively, the formation enthalpy relationship between the second conductor 30 and the interface layer 25 will be described with reference to FIG. 2B.

The second conductor 30 and the interface layer 25 may include the same metal element, that is, titanium. Here, the second conductor 30 is a metal nitride, and the interface layer 25 is a metal oxide.

The formation enthalpy of the titanium nitride contained in the second conductor 30 is higher than that of titanium oxide (TiOₓ) contained in the interface layer 25. In FIG. 2B, since formation enthalpies of various kinds of titanium oxides are lower than the formation enthalpy of the titanium nitride, the interface layer 25 containing titanium oxide may be in a more stable energy state than the second conductor 30 containing titanium nitride.

In order to allow the oxygen atoms contained in the oxide dielectric layer 20 to diffuse into and move to the second conductor 30 containing titanium nitride, the oxygen atoms contained in the oxide dielectric layer 20 would pass through the interface layer 25 containing titanium oxide in a more stable energy state than titanium nitride. However, since the titanium oxide may function as a potential barrier against oxygen diffusion, the interface layer 25 may reduce/prevent diffusion of oxygen atoms from the oxide dielectric layer 20 to the second conductor 30 containing the titanium nitride.

Next, a function performed by the interface layer 25 may be to serve as an oxygen donating layer providing oxygen atoms to the second conductor 30, instead of the oxide dielectric layer 20, during the manufacturing process of the semiconductor device. That is to say, the interface layer 25 may be an oxygen sacrificial layer supplying oxygen.

In the semiconductor device according to first embodiments, the formation enthalpy of the second conductor 30 may be higher than that of the oxide of the interface layer 25, which may be produced by oxidizing the second conductor 30. Referring to FIG. 2B, when the titanium nitride to be contained in the second conductor 30 reacts with oxygen to turn into titanium oxide, the formation enthalpy may be lowered. That is to say, if titanium nitride is oxidized, titanium oxide (which has a more stable energy state than titanium nitride) is produced.

That is to say, if the second conductor 30 is formed on the oxide dielectric layer 20, the second conductor 30 may take oxygen atoms contained in the oxide dielectric layer 20. However, if the oxygen atoms contained in the oxide dielectric layer 20 are taken by the second conductor 30, the capacitance of the oxide dielectric layer 20 may be lowered and the reliability of the dielectric layer 20 may also be reduced.

These disadvantages may be overcome/reduced by introducing the interface layer 25 containing metal oxide. In other words, the interface layer 25 may reduce/prevent diffusion of oxygen atoms contained in the oxide dielectric layer 20 into the second conductor 30 while providing some of the oxygen atoms contained in the interface layer 25 to the second conductor 30. In such a manner, the interface layer 25 may improve electrical characteristics of a structure including the oxide dielectric layer 20 and the second conductor 30.

In detail, when the second conductor 30 is made of a metal nitride and the metal element of the second conductor 30 is bonded with oxygen, forming an oxide, it may become stabilized in view of energy by accepting oxygen atoms supplied from the interface layer 25. However, the oxygen atoms supplied from the interface layer 25 to the second conductor 30 may not form a metal oxide layer with the metal element due to formation conditions of the second conductor 30, and may escape from the second conductor 30, but aspects of present inventive concepts are not limited thereto.

During the manufacturing process of the semiconductor device, the interface layer 25 is formed such that the number of oxygen atoms bonded for each metal atom is relatively low. In other words, during the manufacturing process of the semiconductor device, the interface layer 25 is formed from a pre-interface layer (25a of FIG. 9). That is to say, the oxygen atoms remaining while the pre-interface layer is converted to the interface layer 25 may be supplied to an ambient layer, that is, the second conductor 30 or the oxide dielectric layer 20. Since the oxide dielectric layer 20 is to be formed according to the stoichiometry, the remaining oxygen atoms produced from the interface layer 25 may be supplied to the second conductor 30.

In addition, before the interface layer 25 is formed, a pre-interface layer may be formed to have a stoichiometric composition. Therefore, the interface layer 25, formed when the pre-interface layer loses oxygen atoms, may include a compound having a nonstoichiometric composition. That is to say, materials forming the interface layer 25 are bonded to each other with a composition ratio not satisfying the stoichiometry,

In other words, a concentration of oxygen contained in the interface layer 25 may be smaller than that of the oxygen contained in a pre-interface layer formed to have the stoichiometric composition.

Referring to FIG. 2B, for example, a pre-interface layer may include TiO₂ having a stoichiometric composition, while the interface layer 25 formed when the pre-interface layer loses some oxygen atoms may include TiOₓ, where 0<x<2, which does not have the stoichiometric composition. When oxygen concentrations of TiO₂ and TiOₓ are compared, the concentration of the oxygen contained in TiO₂ contained in the pre-interface layer is greater than that of the oxygen contained in TiOₓ contained in the interface layer 25.

Next, reducing/preventing diffusion of nitrogen atoms contained in the second conductor 30 into the oxide dielectric layer 20, which may be a function of the interface layer 25, will be described. That is to say, the interface layer 25 may serve as a nitrogen diffusion reduction/prevention layer.

As described above, the second conductor 30 may include a metal nitride. In a case where the second conductor 30 is disposed on the oxide dielectric layer 20 without using the interface layer 25, nitrogen atoms contained in the second conductor 30 may diffuse into the oxide dielectric layer 20, so that oxynitride may be formed in the oxide dielectric layer 20.

When an oxynitride layer is formed due to diffusion of nitrogen atoms into the oxide dielectric layer 20, a crystallization temperature of the oxide dielectric layer 20 may rise. In detail, the crystallization temperature of the oxide dielectric layer 20 may be higher than that of the oxide dielectric layer 20 with the nitrogen atoms diffused therein.

Thus, during the manufacturing process of the semiconductor device, to crystallize the deposited oxide dielectric layer 20, it may be necessary to anneal the oxide dielectric layer 20 at a higher temperature. If the oxide dielectric layer 20 with the nitrogen atoms diffused therein is crystallized at a crystallization temperature of the oxide dielectric layer 20 without nitrogen atoms, the oxide dielectric layer 20 with the nitrogen atoms may not be properly crystallized, reducing crystallinity of the oxide dielectric layer 20.

However, the interface layer 25 capable of reducing/preventing penetration/diffusion of nitrogen into the oxide dielectric layer 20 is inserted between the oxide dielectric layer 20 and the second conductor 30, thereby allowing crystallization of the oxide dielectric layer 20 at a relatively low temperature. Accordingly, the crystallinity of the oxide dielectric layer 20 can be improved.

In semiconductor devices according to some embodiments, the interface layer 25 is formed only between the oxide dielectric layer 20 and the second conductor 30 and not between the oxide dielectric layer 20 and the first conductor 10. That is to say, interface layers 25 are not symmetrically formed at opposite sides of the oxide dielectric layer with the oxide dielectric layer 20 interposed therebetween. Since the interface layer having second formation enthalpy H2 is not formed between the first conductor 10 and the oxide dielectric layer 20, oxygen atoms from the oxide dielectric layer 20 may more easily diffuse to the first conductor 10. Stated in other words, a barrier layer capable of reducing/preventing oxygen diffusion may be omitted between the first conductor 10 and the oxide dielectric layer 20.

A semiconductor device according to second embodiments of present inventive concepts will be described with reference to FIG. 3. Since the embodiment of FIG. 3 is similar to the first embodiment of FIG. 1, except that an insertion layer is further formed between an interface layer and an oxide dielectric layer, elements/layers that are the same as those of FIG. 1 are denoted by the same reference numerals, and repeated descriptions thereof will be briefly made or will be omitted.

FIG. 3 illustrates a semiconductor device according to second embodiments of present inventive concepts,

Referring to FIG. 3, the semiconductor device 2 according to second embodiments includes a first conductor 10, an oxide dielectric layer 20, an insertion layer 23, an interface layer 25, and a second conductor 30.

The oxide dielectric layer 20, the interface layer 25 and the second conductor 30 are sequentially formed on the first conductor 10.

The insertion layer 23 is provided between the oxide dielectric layer 20 and the interface layer 25. The insertion layer 23 is formed to be in contact with the interface layer 25. That is to say, the interface layer 25 may be in direct contact with the insertion layer 23 and the second conductor 30, between the insertion layer 23 and the second conductor 30. Along with the interface layer 25, the insertion layer 23 may prevent/reduce diffusion of oxygen atoms contained in the oxide dielectric layer 20 into the second conductor 30. That is to say, the insertion layer 23 may be another oxygen diffusion reducing/preventing layer, which can supplement the oxygen diffusion preventing/reducing function performed by the interface layer 25.

The insertion layer 23 may include an oxygen containing compound. In greater detail, the insertion layer 23 may include aluminum oxide (Al₂O₃). Aluminum contained in the insertion layer 23 may exist in the insertion layer 23 in the form of an Al³⁺ ion, having relatively strong oxygen affinity. Therefore, the insertion layer 23 may prevent/reduce diffusion of oxygen contained in the oxide dielectric layer 20 into the second conductor 30 through the insertion layer 23.

In order to prevent/reduce lowering of a dielectric constant of the oxide dielectric layer 20 and/or to reduce/minimize the interface layer 25 from functioning as a dielectric layer, the insertion layer 23 may have a thickness in a range of, for example, 1 Å (Angstrom) to 5 Å (Angstroms), In addition, the thickness of the insertion layer 23 may be less than that of the interface layer 25.

In the semiconductor device according to second embodiments, an oxygen diffusion preventing/reducing layer (to prevent/reduce oxygen diffusion in the oxide dielectric layer 20) may have a double layered structure including the interface layer 25 and the insertion layer 23.

Although the oxygen diffusion preventing/reducing layer on the oxide dielectric layer 20 has a double layered structure, the interface layer 25 of the oxygen diffusion preventing/reducing layer is a conductive layer and the insertion layer 23 of the oxygen diffusion preventing/reducing layer is a dielectric layer.

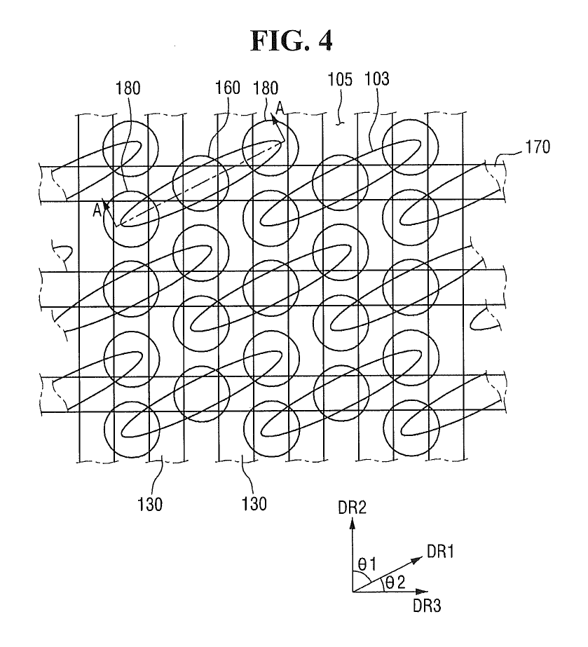

The use semiconductor devices 1 and 2 shown in FIGS. 1 and 3, for information storage units of memory devices will now be described with reference to FIGS. 4 to 6. In the following description, the information storage units are capacitors, but aspects of present inventive concepts are not limited thereto.

FIG. 4 is a layout view illustrating semiconductor devices according to third and fourth embodiments of present inventive concepts. That is to say, FIG. 4 is a layout view illustrating semiconductor devices prior to formation of the information storage units (i.e., capacitors).

Referring to FIG. 4, in the semiconductor device according to second embodiments, a unit active region(s) 103 is defined by forming an isolation region(s) 105 in a substrate 100.

In greater detail, each unit active region 103 extends in a first direction DR1, each gate electrode (that is, word line) 130 extends in a second direction DR2 (which forms an acute angle with respect to the first direction DR1), and each bit line 170 extends in a third direction D3, which forms an acute angle with respect to the first direction DR1.

Here, the term “angle” used in the phrase “a predetermined angle formed between a particular direction and another particular direction” may mean a smaller angle of two angles formed when two directions cross each other, for example, 60° in a case where angles formed by two crossing directions are 120° and 60°. Therefore, as shown in FIG. 4, an angle formed by the first direction DR1 and the second direction DR2 is θ1, and an angle formed by the first direction DR1 and the third direction DR3 is θ2.

As described above, θ1 and/or θ2 are established as acute angles for the purpose of providing an increased/maximum distance between a bit line contact 160 connecting the unit active region 103 and the bit line 170, and a storage node contact 180 (i.e., a second contact plug of FIG. 5) connecting the unit active region 103 and the capacitor. For example, θ1 and θ2 may be 45° and 45°, 30° and 60°, or 60° and 30°, respectively, but aspects of present inventive concepts are not limited thereto. More generally, the second and third directions may be orthogonal second and third directions, and the first direction may be non-orthogonal with respect to both of the second and third directions.

Next, a semiconductor device according to third embodiments of present inventive concepts will be described with reference to FIG. 5.

FIG. 5 illustrates a semiconductor device according to third embodiments of present inventive concepts. Specifically, FIG. 5 is a cross-sectional view taken along the line AA of FIG. 1, illustrating an example of a semiconductor device including a capacitor.

Referring to FIG. 5, a semiconductor device 3 includes a substrate 100, a transistor T, a bit line 170 and a capacitor C.

A unit active region 103 and an isolation region 105 are formed on a substrate 100. The substrate 100 may be a bulk silicon or a silicon-on-insulator (SOI) substrate. Alternatively, the substrate 100 may be a silicon substrate or a substrate made of another material such as germanium, indium antimonide, lead telluride, indium arsenide, indium phosphide, gallium arsenide, or gallium antimonide. In the following description, a silicon substrate is exemplified. The isolation region 105 may be formed by a shallow trench isolation (STI) process. In FIG. 4, the unit active region 103 extending in the first direction DR1 may be defined by the isolation region 105.

Two transistors T may be formed in one unit active region 103. The two transistors T may include two gate electrodes 130 formed to cross the unit active region 103, a first impurity region 107a formed in the unit active region 103 between the two gate electrodes 130, and second impurity regions 107b formed between each of the gate electrodes 130 and the respective isolation region 105. That is to say, the two transistors T may share the first impurity region 107a while not sharing the respective second impurity regions 107b.

Each of the two transistors T may include a gate insulation layer 120, a gate electrode 130 and a capping pattern 140.

The gate insulation layer 120 may be formed along lateral surfaces and a bottom surface of a trench 110 formed in the substrate 100. The gate insulation layer 120 may include, for example, silicon oxide or a high-k dielectric having a higher dielectric constant than silicon oxide. In FIG. 5, the gate insulation layer 120 may be entirely formed on the entirety of the lateral surfaces of the trench 110, but aspects of present inventive concepts are not limited thereto. That is to say, the gate insulation layer 120 may be formed to be in contact with lower portions of the lateral surfaces of the trench 110, and a capping pattern 140 (to be described later) may be formed to be in contact with upper portions of the lateral surfaces of the trench 110.

The gate electrode 130 may be formed to fill a portion of the trench 110, rather than completely filling the trench 110. Stated in other words, the gate electrode 130 may be recessed. The gate electrode 130 may be formed using, for example, doped polysilicon, titanium nitride (TiN), tantalum nitride (TaN), tungsten nitride (WN), titanium (Ti), tantalum (Ta), and/or tungsten (W), but the gate electrode is not limited thereto. The capping pattern 140 may be formed on the gate electrode 130 to fill the trench 110. The capping pattern 140 may be made of an insulating material, and may include, for example, at least one of silicon oxide, silicon nitride, and/or silicon oxynitride. In FIG. 5, the capping pattern 140 fills a portion of trench 110 between the gate electrode 130 and dielectric layer 150 and between portions of the gate insulation layer 120 formed on opposite sidewalls of the trench 110, but aspects of present inventive concepts are not limited thereto. For example, the capping pattern 140 may be formed in contact with the substrate 100, that is, the first impurity region 107a and the second impurity region 107b.

In the semiconductor device according to third embodiments, the transistor T is a buried channel array transistor (BCAT), but aspects of present inventive concepts are not limited thereto. For example, the transistor T may have various structures including a planar transistor or a pillar-shaped vertical channel array transistor (VCAT) structure.

An interlayer dielectric layer 150 may be formed on the substrate 100. The interlayer dielectric layer 150 may include, for example, at least one of silicon oxide, silicon nitride, and/or silicon oxynitride. The interlayer dielectric layer 150 may be formed of a single layer or multiple layers.

A first contact plug (bit line contact) 160 (electrically connected to the first impurity region 107a) may be formed in the interlayer dielectric layer 150. The first contact plug 160 may be made of a conductive material, and may include, for example, at least one of polysilicon, a metal silicide compound, and/or a metal, but aspects of present inventive concepts are not limited thereto. A bit line 170 (electrically connected through first contact plug 160 to the first impurity region 107a) may be formed on the first contact plug 160. The bit line 170 may be made of a conductive material, and may include, for example, at least one of polysilicon, a metal silicide compound, a conductive metal nitride, and/or a metal, but aspects of present inventive concepts are not limited thereto.

A second contact plug 180 may be formed through the interlayer dielectric layer 150. The second contact plug 180 may be electrically connected to a second impurity region 107b. The second contact plug 180 may be a storage node contact. The second contact plug 180 may be made of a conductive material, and may include, for example, at least one of polysilicon, a metal silicide compound, a conductive metal nitride, and/or a metal, but aspects of present inventive concepts are not limited thereto.

A capacitor C (electrically connected to the second impurity region 107b) may be formed on the interlayer dielectric layer 150. The capacitor C may be electrically connected to the second impurity region 107b through the second contact plug 180.

The capacitor C may include a lower electrode 200, a capacitor dielectric layer 210, a capacitor interface layer 220, and an upper electrode 230.

Referring to FIGS. 1 and 3, the lower electrode 200 may be a first conductor 10, the capacitor dielectric layer 210 may be an oxide dielectric layer 20, and the upper electrode 230 may be a second conductor 30. In addition, the capacitor interface layer 220 may be formed as an interface layer 25 as shown in FIG. 1, or as a double layer including the interface layer 25 and the insertion layer 23 as shown in FIG. 3.

The lower electrode 200 may be formed to protrude from the substrate 100 and may be electrically connected to the second contact plug 180. The lower electrode 200 protruding from the substrate 100 may extend lengthwise in one direction, that is, in a thickness direction of the substrate 100.

In the semiconductor device according to third embodiments, the lower electrode 200 may have a cylindrical shape with inner and outer sidewalls. The cylindrical shape shown in FIG. 5 is provided only for illustration, but aspects of present inventive concepts are not limited thereto. Stated in other words, the lower electrode 200 may have various shapes.

The capacitor dielectric layer 210 is formed on the lower electrode 200. The capacitor dielectric layer 210 may be formed along the inner and outer sidewalls of the cylindrical lower electrode 200.

The capacitor interface layer 220 is formed on the capacitor dielectric layer 210. As described above with reference to FIGS. 1 and 3, the capacitor interface layer 220 may be formed of the interface layer 25 made of a metal oxide and may have formation enthalpy H2. If the capacitor interface layer 220 has a double layered structure including the interface layer 25 and the insertion layer 23, as shown in FIG. 3, it may further include an Al₂O₃ layer formed on the capacitor dielectric layer 210.

The upper electrode 230 is formed on the capacitor interface layer 220 to be in contact with the capacitor interface layer 220. The upper electrode 230 may include, for example, a metal nitride. The metal nitride included in the upper electrode 230 has formation enthalpy H1 higher than formation enthalpy H2 of the metal oxide forming the capacitor interface layer 220.

In FIG. 5, the upper electrode 230 is formed on the interlayer dielectric layer 150 to have a plate shape, but aspects of present inventive concepts are not limited thereto. The upper electrode 230 may be formed along the inner and outer sidewalls of the cylindrical lower electrode 200.

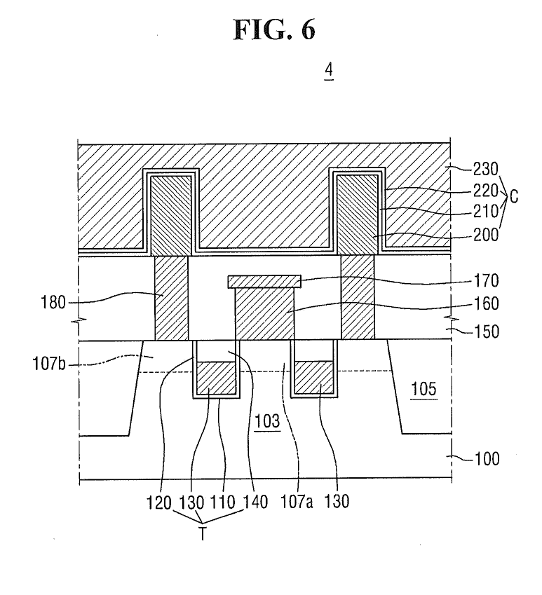

A semiconductor device according to fourth embodiments of present inventive concepts will now be described with reference to FIG. 6. Since this embodiment is substantially the same as the third embodiment, except for the shape of a lower electrode, elements/layers that are substantially the same as those of the previous embodiment are denoted by the same reference numerals, and repeated descriptions thereof may be briefly made or omitted.

FIG. 6 illustrates the semiconductor device according to fourth embodiments of present inventive concepts. Specifically, FIG. 6 is a cross-sectional view taken along the line AA of FIG. 4, illustrating an exemplary semiconductor device including a capacitor.

Referring to FIG. 6, the semiconductor device 4 according to fourth embodiments may include a substrate 100, a transistor T, a bit line 170, and a capacitor C.

The lower electrode 200 is formed to protrude from substrate 100 and is electrically connected to a second contact plug 180. The lower electrode 200 protruding from substrate 100 may extend lengthwise in one direction, that is, in a thickness direction of the substrate 100.

In the semiconductor device according to fourth embodiments, the lower electrode 200 may be pillar shaped. The pillar shape shown in FIG. 6 is provided only for illustration, but aspects of present inventive concepts are not limited thereto. That is to say, the lower electrode 200 may have various shapes.

The capacitor dielectric layer 210 and the capacitor interface layer 220 are formed along the outer sidewalls of the lower electrode 200.

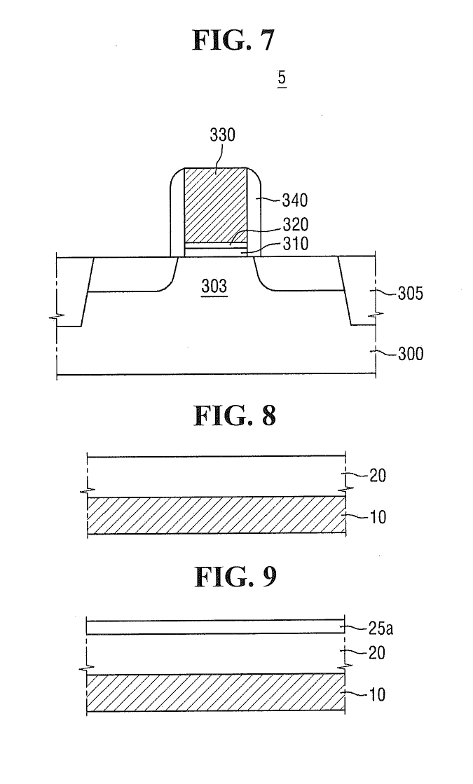

A semiconductor device according to fifth embodiments of present inventive concepts will now be described with reference to FIG. 7. FIG. 7 illustrates embodiments of semiconductor devices 1 and 2 of FIGS. 1 and 3 used as components of a transistor.

FIG. 7 illustrates a semiconductor device according to fifth embodiments of present inventive concepts.

Referring to FIG. 7, the semiconductor device 5 according to fifth embodiments may include a substrate 300, a gate insulation layer 310, a gate interface layer 320, and a gate electrode 330.

An active region 303 and an isolation region 305 are formed on/in a substrate 300. The substrate 300 may be bulk silicon or a silicon-on-insulator (SOI) substrate. Alternatively, the substrate 300 may be a silicon substrate or a substrate made of another material such as germanium, indium antimonide, lead telluride, indium arsenide, indium phosphide, gallium arsenide, and/or gallium antimonide, but not limited thereto.

A channel region of the transistor formed on/in the active region 303 of the substrate 300 may be a first conductor 10, the gate insulation layer 310 may be an oxide dielectric layer 20, and the gate electrode 330 may be a second conductor 30. In addition, the gate interface layer 320 may include interface layer 25 as shown in FIG. 1, or may be a double layer including interface layer 25 and insertion layer 23 of FIG. 3.

The gate interface layer 320 is formed on the gate insulation layer 310. As described above with reference to FIGS. 1 and 3, the gate interface layer 320 may be formed of metal oxide interface layer 25. If the gate interface layer 320 has a double layer structure including interface layer 25 and insertion layer 23, as shown in FIG. 3, it may further include an Al₂O₃ layer formed on the capacitor dielectric layer 310. If the transistor is a PMOS transistor, N-type impurity is doped into the active region 303 on opposite sides of electrode 330, and if the transistor is an NMOS transistor, P-type impurity is doped into the active region 303 on opposite sides of electrode 330.

In semiconductor devices according to fifth embodiments, the transistor is a planar transistor, but aspects of present inventive concepts are not limited thereto. The transistor may have various structures including a buried channel array transistor (BCAT), a vertical channel array transistor (VCAT), and so on.

In FIG. 7, the gate insulation layer 310 and the gate interface layer 320 are formed to be parallel with a top surface of the substrate 100, but aspects of present inventive concepts are not limited thereto. For example, portions of gate insulation layer 310 and/or gate interface layer 320 may extend in a thickness direction of the substrate 300.

Hereinafter, methods for fabricating semiconductor devices according to first embodiments of present inventive concepts will be described with reference to FIGS. 1, 2A and 8 to 10.

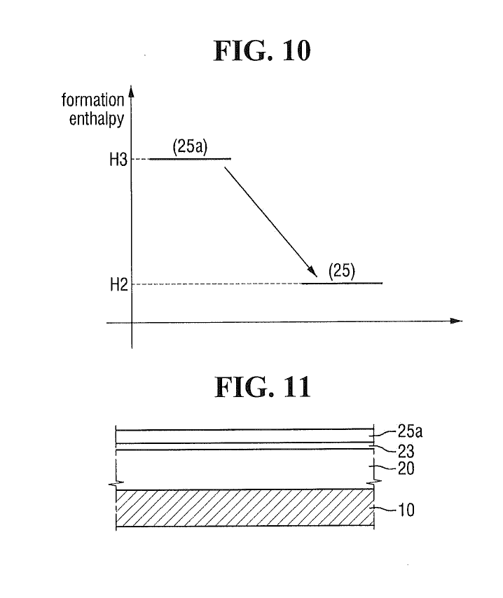

FIGS. 8 and 9 illustrate intermediate process operations of a method for fabricating the semiconductor device according to first embodiments of present inventive concepts, and FIG. 10 is a diagram illustrating a change in formation enthalpy generated in an interface layer in the course of forming a second conductor.

Referring to FIG. 8, a first conductor 10 and an oxide dielectric layer 20 are sequentially formed. Stated in other words, the oxide dielectric layer 20 is formed on the first conductor 10.

The first conductor 10 may be a lower electrode of an information storage unit, and may include, for example, at least one selected from the group consisting of doped polysilicon, a conductive metal nitride (such as titanium nitride (TiN), tantalum nitride (TaN), and/or tungsten nitride (WN), a metal (such as ruthenium (Ru), iridium (Ir), titanium (Ti), and/or tantalum (Ta)), and/or a conductive metal oxide (such as iridium oxide). According to other embodiments, the first conductor 10 may be a channel region of a transistor, in a doped substrate, for example, a P-type substrate or an N-type substrate.

The oxide dielectric layer 20 may be, for example, a high-k dielectric layer, and may include zirconium oxide (ZrO₂), hafnium oxide (HfO₂), zirconium silicon oxide (ZrSiOₓ), hafnium silicon oxide (HfSiOₓ), zirconium hafnium silicon oxide (ZrHfSiOₓ), aluminum oxide (Al₂O₃), and/or combinations thereof. The oxide dielectric layer 20 may be formed by, for example, atomic layer deposition (ALD), chemical vapor deposition (CVD), and/or sputtering.

Referring to FIG. 9, a pre-interface layer 25a is formed on the oxide dielectric layer 20. The pre-interface layer 25a may have a formation enthalpy H3.

The pre-interface layer 25a may include, for example, one of titanium oxide (TiOₓ, where 0<x<2), aluminum oxide (AlOₓ, where 1<x<2), titanium aluminum oxide (Ti_{y}Al_{1=y}Oₓ, where 0<x<2), and/or manganese oxide (MnOₓ where 0<x<2). If the pre-interface layer 25a is titanium aluminum oxide, a ratio of a metal element in the pre-interface layer 25a to an aluminum element may be in a range of, for example, 0.001 to 0.5.

The pre-interface layer 25a may be formed by, for example, atomic layer deposition (ALD) or chemical vapor deposition (CVD).

Referring to FIGS. 1 and 10, the second conductor 30 is formed on the pre-interface layer 25a to be in contact with the pre-interface layer 25a.

The second conductor 30 may be made of a conductive metal nitride and may include, for example, one of titanium nitride (TiN), zirconium nitride (ZrN), aluminum nitride (AIN), hafnium nitride (HfN), tantalum nitride (TaN), niobium nitride (NbN), yttrium nitride (YN), lanthanium nitride (LaN), vanadium nitride (VN), and/or manganese nitride (Mn₄N).

The second conductor 30 may be formed by, for example, atomic layer deposition (ALD) and/or chemical vapor deposition (CVD).

During formation of the second conductor 30, the pre-interface layer 25a may be converted into the interface layer 25, so that the interface layer 25 is formed between the second conductor 30 and the oxide dielectric layer 20.

The formation enthalpy H2 of the interface layer 25 is lower than the formation enthalpy H3 of the pre-interface layer 25a. That is to say, during formation of the second conductor 30, the pre-interface layer 25a may be converted into the interface layer 25 having lower formation enthalpy than the pre-interface layer 25a.

In addition, the formation enthalpy H2 of the interface layer 25 produced from the pre-interface layer 25a is lower than the formation enthalpy H1 of the second conductor 30. That is to say, the formation enthalpy H1 of the second conductor 30 is higher than the formation enthalpy H2 of the interface layer 25.

During formation of the second conductor 30, the pre-interface layer 25a may provide some oxygen atoms contained therein to the second conductor 30. At the same time, the pre-interface layer 25a may prevent/reduce diffusion of oxygen atoms from the oxide dielectric layer 20 into the second conductor 30. In addition, the pre-interface layer 25a may prevent/reduce penetration/diffusion of nitrogen atoms (provided when the second conductor 30 is formed) into the oxide dielectric layer 20.

Since some oxygen atoms contained in the pre-interface layer 25a may be provided to the second conductor 30, a number of oxygen atoms bonded for each metal atom in the pre-interface layer 25a is greater than a number of oxygen atoms bonded for each metal atom in the interface layer 25. That is to say, a reaction in which the pre-interface layer 25a is converted into the interface layer 25 is a reduction, and oxidation enthalpy of the reaction in which the pre-interface layer 25a turns into the interface layer 25 has a positive value.

Since oxygen atoms are provided from the pre-interface layer 25a to the second conductor to then form the interface layer 25, oxygen vacancies may be formed in the interface layer 25. The oxygen vacancies in the interface layer 25 (a kind of defects), may serve as a path for the flow of current. Therefore, the interface layer 25 may be made of a metal oxide that is electrically conductive.

In methods for fabricating the semiconductor devices according to embodiments of present inventive concepts, the pre-interface layer 25a may be formed of a compound satisfying stoichiometry, but aspects of present inventive concepts are not limited thereto. For example, the pre-interface layer 25a may be made of an oxygen rich metal oxide having excessive oxygen atoms included in the metal oxide satisfying stoichiometry.

Methods for fabricating semiconductor devices according to second embodiments of present inventive concepts will now be described with reference to FIGS. 2A, 3 and 11. Since these embodiments may be substantially the same as first embodiments, except that an insertion layer is further provided, layers/elements that are the same as those of the previous embodiments are denoted by the same reference numerals, and repeated descriptions thereof may be briefly made or omitted.

FIG. 11 illustrates intermediate process steps in a method for fabricating semiconductor devices according to second embodiments of present inventive concepts.

Referring to FIG. 11, a first conductor 10, an oxide dielectric layer 20, an insertion layer 23 and a pre-interface layer 25a are sequentially formed. The pre-interface layer 25a and the insertion layer 23 are formed to directly contact each other.

The insertion layer 23 may include, for example, an oxygen-containing compound, such as an aluminum oxide (Al₂O₃). The insertion layer 23 may be formed by, for example, atomic layer deposition (ALD) and/or chemical vapor deposition (CVD).

Referring to FIGS. 3 and 10, a second conductor 30 is formed on the pre-interface layer 25a to be in contact with the pre-interface layer 25a.

During formation of the second conductor 30, the pre-interface layer 25a is converted into an interface layer 25, so that the interface layer 25 is formed between the second conductor 30 and the insertion layer 23.

During formation of the second conductor 30, along with the pre-interface layer 25a, the insertion layer 23 may reduce/prevent diffusion of oxygen atoms from the oxide dielectric layer 20 into the second conductor 30. In addition, the pre-interface layer 25a and the insertion layer 23 may reduce/prevent penetration/diffusion of nitrogen atoms (provided when the second conductor 30 is formed) into the oxide dielectric layer 20.

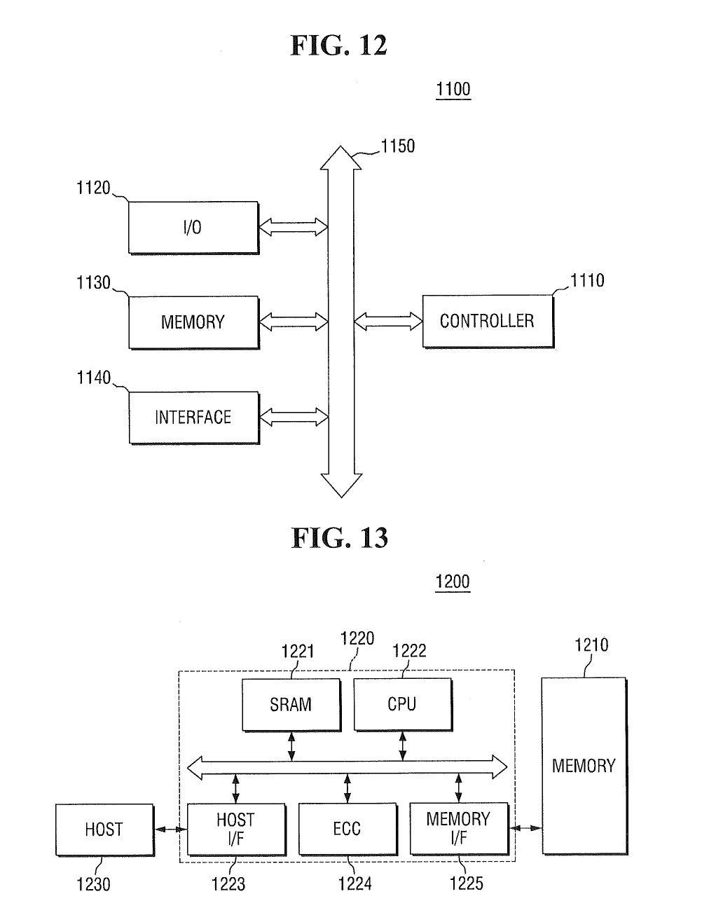

FIG. 12 is a block diagram illustrating an exemplary electronic system including semiconductor devices according to embodiments of present inventive concepts.

Referring to FIG. 12, the electronic system 1100 according to some embodiments of present inventive concepts may include a controller 1110, an input/output (I/O) device 1120, a memory device 1130, an interface 1140, and a bus 1150. The controller 1110, the I/O device 1120, the memory device 1130, and/or the interface 1140 may be connected to each other through the bus 1150. The bus 1150 may provide path through which data moves.

The controller 1110 may include at least one of a microprocessor, a digital signal processor, a microcontroller, and logic devices capable of performing similar functions to those performed by these devices. The I/O device 1120 may include a keypad, a keyboard, a display device, and the like. The memory device 1130 may store data and/or instructions. The memory device 1130 may include semiconductor devices according to embodiments of present inventive concepts. For example, the memory device 1130 may include a DRAM. The interface 1140 may transmit/receive data to/from a communication network. The interface 1140 may be wired or wireless. For example, the interface 1140 may include an antenna and/or a wired/wireless transceiver.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

FIG. 13 is a block diagram illustrating an example of a memory card including semiconductor devices according to embodiments of present inventive concepts.

Referring to FIG. 13, the memory 1210 including the semiconductor devices according to various embodiments of present inventive concepts may be employed in a memory card 1200. The memory card 1200 may include a memory controller 1220 controlling data exchange between host 1230 and memory 1210. A static random access memory (SRAM) 1221 may be used as an operating memory of a central processing unit 1222. A host interface 1223 may include a protocol for exchanging data by allowing the host 1230 to be connected to the memory card 1200. An error correction code (ECC) 1224 may detect an error from data read from the memory 1210 to then correct the detected error. A memory interface 1225 may interface with the memory 1210. The central processing unit 1222 may perform overall control operations associated with the data exchange of the memory controller 1220.

According to some embodiments, dielectric layers 20, 210, and/or 310 may be provided as dielectric oxide stacks. For example, dielectric oxide layer 20, 210, and/or 310 may include an aluminum oxide layer between first and second zirconium oxide layers.

While present inventive concepts have been particularly shown and described with reference to examples of embodiments thereof, it will be understood by those of ordinary skill in the art that various changes in form and details may be made therein without departing from the spirit and scope of present inventive concepts as defined by the following claims. It is therefore desired that present embodiments be considered in all respects as illustrative and not restrictive, reference being made to the appended claims rather than the foregoing description to indicate the scope of present inventive concepts.

1. An electronic device comprising:
a substrate;
an oxide dielectric layer on the substrate, wherein the oxide dielectric layer includes an aluminum oxide layer between first and second zirconium oxide layers;
an interface layer on the oxide dielectric layer, wherein the interface layer has a first formation enthalpy, and wherein the oxide dielectric layer is between the substrate and the interface layer; and
an electrode on the interface layer, wherein the electrode has a second formation enthalpy higher than the first formation enthalpy, and wherein the interface layer is between the oxide dielectric layer and the electrode.

2. The electronic device of claim 1 wherein the interface layer comprises an oxide of at least one of titanium (Ti), aluminum (Al), and/or manganese (Mn).

3. The electronic device of claim 2 wherein the interface layer comprises at least one of TiₓO_{y}, AlₓO_{y}, TiₓAl_{z}O_{y}, and/or MnₓO_{y}, where a ratio of a number of oxygen atoms to a number of metal atoms is in the range of 1 to 2.

4.-21. (canceled)

22. An electronic device comprising:
a substrate;
an oxide dielectric layer on the substrate, wherein the oxide dielectric layer includes an aluminum oxide layer between first and second zirconium oxide layers;
an interface layer on the oxide dielectric layer, wherein the interface layer comprises an oxide of at least one of titanium (Ti), aluminum (Al), and/or manganese (Mn), and wherein the oxide dielectric layer is between the substrate and the interface layer; and
an electrode on the interface layer, and wherein the interface layer is between the oxide dielectric layer and the electrode.

23. The electronic device of claim 22 wherein the interface layer comprises at least one of TiₓO_{y}, AlₓO_{y}, TiₓAl_{z}O_{y}, and/or MnₓO_{y}, where a ratio of a number of oxygen atoms to a number of metal atoms is in the range of 1 to 2.

24.-26. (canceled)

27. The electronic device of claim 22 wherein the interface layer comprises at least one of TiO₂, Ti₄O₇, Ti₃O₅, and/or Ti₂O₃.

28. The electronic device of claim 22 wherein the electrode comprises a conductive metal nitride.

29. (canceled)

30. The electronic device of claim 22 wherein the interface layer comprises an oxide of a selected one of titanium, aluminum, manganese, or titanium and the electrode comprises a nitride of the selected one of titanium aluminum, manganese, or titanium.

31. (canceled)

32. The electronic device of claim 22 further comprising:
an insertion layer comprising aluminum oxide layer between the oxide dielectric layer and the interface layer, wherein a material of the interface layer is different than that of the insertion layer.

33.-34. (canceled)

35. The electronic device of claim 22 wherein the electrode comprises a first electrode, the electronic device further comprising:
a second electrode between the substrate and the oxide dielectric layer.

36. The electronic device of claim 22 wherein the substrate includes a semiconductor active region having a channel region between first and second source/drain regions, wherein the oxide dielectric layer is on the channel region between the channel region and the electrode.

37. The electronic device of claim 22 further comprising:
a transistor on the substrate, wherein the transistor includes a channel region, first and second source/drain regions on opposite sides of the channel region, and a word line on the channel region;
a bit line electrically coupled to the first source/drain region;
a first capacitor electrode electrically coupled to the second source/drain region, wherein the oxide dielectric layer is on the first capacitor electrode so that the first capacitor electrode is between the oxide dielectric layer and the substrate, and wherein the oxide dielectric layer is between the first capacitor electrode and the interface layer;
wherein the electrode comprises a second capacitor electrode,

38.-41. (canceled)

42. An electronic device comprising:
a first electrode;
an oxide dielectric layer on the first electrode, wherein the oxide dielectric layer includes an aluminum oxide layer between first and second zirconium oxide layers;
an interface layer on the oxide dielectric layer, wherein the interface layer comprises an oxide of at least one of titanium (Ti), aluminum (Al), and/or manganese (Mn), and wherein the oxide dielectric layer is between the first electrode and the interface layer; and
a second electrode on the interface layer, and wherein the interface layer is between the oxide dielectric layer and the second electrode.

43. The electronic device of claim 42 further comprising:
a substrate wherein the first electrode is between the substrate and the oxide dielectric layer.

44. The electronic device of claim 42 wherein the oxide dielectric layer is thicker than the interface layer.

45. The electronic device of claim 42 wherein the interface layer comprises a titanium oxide layer directly on one of the first and second zirconium oxide layers of the oxide dielectric layer.

46. The electronic device of claim 42 wherein the interface layer comprises an oxide of at least one of titanium (Ti), aluminum (Al), and/or manganese (Man).

47. The electronic device of claim 46 wherein the interface layer comprises at least one of TiₓO_{y}, AlₓO_{y}, TiₓAl_{z}O_{y}, and/or MnₓO_{y}, where a ratio of a number of oxygen atoms to a number of metal atoms is in the range of 1 to 2.

48.-50. (canceled)

51. The electronic device of claim 46 wherein the interface layer comprises at least one of Ti₄O₇, Ti₃O₅, and/or Ti₂O₃.

52. The electronic device of claim 46 wherein the second electrode comprises a conductive metal nitride.

53. (canceled)

54. The electronic device of claim 42 wherein the interface layer comprises an oxide of a metal and the second electrode comprises a nitride of the metal.

55. The electronic device of claim 42 wherein the interface layer has a thickness in the range of about 1 Angstroms to about 10 Angstroms.

56. The electronic device of claim 42 further comprising:
an insertion layer comprising an aluminum oxide layer between the oxide dielectric layer and the interface layer, wherein a material of the interface layer is different than that of the insertion layer.

57. The electronic device of claim 56 wherein the interface layer is directly on the insertion layer.

58. The electronic device of claim 56 wherein the insertion layer has a thickness in the range of about 1 Angstroms to about 5 Angstroms.

59. The electronic device of claim 56 wherein a thickness of the interface layer is greater than a thickness of the insertion layer.

60. The electronic device of claim 56 wherein the oxide dielectric layer is thicker than the interface layer and wherein the interface layer is thicker than the insertion layer.

61. The electronic device of claim 42 further comprising:
a substrate wherein the first electrode is between the substrate and the oxide dielectric layer;
a transistor on the substrate, wherein the transistor includes a channel region, first and second source/drain regions on opposite sides of the channel region, and a word line on the channel region; and
a bit line electrically coupled to the first source/drain region;
wherein the first electrode is electrically coupled to the second source/drain region.

62.-65. (canceled)
